(19) United States
(12) Patent Application Publication
(10) Pub. No.: US 2008/0044970 A1
(43) Pub. Date: Feb. 21, 2008

(54) Memory structure and method for preparing the same

(75) Inventors: Jung Wu Chien, Hsinchu City (TW); Chia Shun Hsiao, Hsinchu (TW)

Correspondence Address: OLIFF & BERRIDGE, PLC, P.O. BOX 320850, ALEXANDRIA, VA, 22320-4850, US

(73) Assignee: PROMOS TECHNOLOGIES INC., Hsinchu (TW)

(21) Appl. No.: 11/516,627

(22) Filed: Sep. 7, 2006

(30) Foreign Application Priority Data
Aug. 18, 2006 (TW) 095130376

(51) Int. Cl. H01L 21/8244; H01L 21/8234

(52) U.S. Cl. 438/238

(57) ABSTRACT

A memory structure comprises a semiconductor substrate, an active are positioned in the semiconductor substrate, a plurality of doped regions positioned in the semiconductor substrate, a first conductive plug connecting a bit line and one of the doped regions and a second conductive plug connecting a capacitor and another one of doped regions. The first conductive plug includes a first block positioned in the active area and a second block positioned at a first side of the active area, and the bit line electrically connects the second block. The second conductive plug includes a third block positioned in the active area and a fourth block positioned at a second side of the active area, and the capacitor electrically connects the fourth block. The first side of the active area is opposite to the second side of the active area.

### BACKGROUND OF THE INVENTION

(A) Field of the Invention

The present invention relates to a memory structure and method for preparing the same, and more particularly, to a memory structure having conductive plugs extending to opposite sides of an active area and method for preparing the same.

(B) Description of the Related Art

Recently, the number of memory cells and the storage density of the dynamic random access memory (DRAM) has increased with the innovation of semiconductor fabrication technology rapidly. Each memory cell of the DRAM generally consists of a metal oxide semiconductor field effect transistor (MOSFET) and a capacitor on a silicon substrate, and the MOSFET includes a source terminal electrically connected to an upper storage plate of the capacitor. There are two types of capacitors: stack capacitors and deep trench capacitors. The stack capacitor is fabricated on the surface of the semiconductor substrate, while the deep trench capacitor is fabricated inside the semiconductor substrate.

FIG. 1 shows a conventional DRAM 100 disclosed by employed researchers of Samsung Electronics in 2005 Symposium on VLSI Technology Digest of Technical Papers. The DRAM 100 comprises a plurality of word lines 102, a plurality of bit lines 104, a plurality of tilt active areas 106, a bit line contact plug 108 positioned at the middle of the active area 106, and two capacitor contact plugs 110 positioned at two sides of the active area 106. The DRAM 100 is designed with a 6F² memory cells, i.e., 2F(word line)×3F(bit line)=6F², wherein F represents the critical dimension.

However, the preparation of the DRAM 100 needs to use the double exposure technique for patterning the electrically isolated tile active areas 106, and the double exposure technical is still not available in the exposure machine used in the nowadays semiconductor fabrication. In addition, the size of the capacitor contact plug 100 between two word lines 102 is 1F, which needs the advanced lithographic technique such as liquid immersion lithographic technique to precisely define the size and position of the capacitor plug 110.

FIG. 2 shows another conventional DRAM 120 disclosed by employed researchers of Micron technology in 2004 Symposium on VLSI Technology Digest of Technical Papers. The DRAM 120 comprises a plurality of word lines 122, a plurality of tilt bit lines 124, a plurality of tilt active area 126, a bit line contact plug 128 positioned at the middle of the active area 126, and two capacitor contact plugs 130 positioned at two sides of the tilt active area 126. In comparison with the DRAM 100 having a tilt active area 106 as shown in FIG. 1, the active area 126 and the bit lines 124 of the DRAM 120 both are tilted. In addition, the bit line contact plug 128 is positioned right at the intersection of the tilt active area 126 and the tilt bit line 124.

### SUMMARY OF THE INVENTION

One aspect of the present invention provides a memory structure having conductive plugs extending to opposite sides of an active area to decrease precision demand on advanced lithographic technique.

A memory structure according to this aspect of the present invention comprises a semiconductor substrate, an active area positioned in the semiconductor substrate, a plurality of doped regions positioned in the semiconductor substrate, a first conductive plug electrically connecting a bit line and one of the doped regions, and a second conductive plug electrically connecting a capacitor and another one of the doped regions. The first conductive plug includes a first block positioned in the active area and a second block positioned at a first side of the active area, and the bit line connects the second block via a bit line contact plug. The second conductive plug includes a third block positioned in the active area and a fourth block positioned at a second side of the active area, and the capacitor connects the fourth block via a capacitor contact plug. Preferably, the width of the first block is substantially twice as large as the width of second block, the width of the third block is substantially twice as large as the width of fourth block, and the first side and the second side of the active area are opposite sides of the active area.

Another aspect of the present invention provides a method for preparing a memory structure comprising the steps of forming a first etching mask on a substrate having a dielectric structure, removing a portion of the dielectric structure to form a plurality of dielectric pillars and a plurality of first openings between the dielectric pillars, forming a second etching mask covering a portion surface of the dielectric pillars, removing a portion of the dielectric pillars to enlarge the first openings to form a plurality of second openings, and forming a plurality of conductive plugs in the second openings.

To form the second etching mask, a deposition process is performed to form a silicon-containing layer covering the dielectric pillars, and at least one tilt implanting process is performed to implant dopants such as boron fluoride into a predetermined portion of the silicon-containing layer to change the chemical property thereof. Subsequently, a wet etching process using ammonia as etchant is performed to remove a portion of the silicon-containing layer other than the predetermined portion to form the second etching mask. Preferably, a third implanting mask covering a bottom portion of the first openings is formed before the tile implanting process to prevent the subsequent tilt implanting process from implanting dopants into the semiconductor substrate via the first opening.

The conventional memory structure needs the double exposure technique and the advanced lithographic technique to precisely define the size and the position of the capacitor contact plug, i.e., the contact hole, as the integrated circuit technique proceeds into the nanometer generation (F is smaller than 100 nanometers). In comparison, the preparation of the present memory structure does not need the double exposure technique, and patterning the size and the position of the contact hole does not need the advanced lithographic technique such as liquid immersion lithographic technique.

### BRIEF DESCRIPTION OF THE DRAWINGS

The objectives and advantages of the present invention will become apparent upon reading the following description and upon reference to the accompanying drawings in which:

FIG. 1 shows a conventional DRAM;

FIG. 2 shows another conventional DRAM;

FIG. 3 to FIG. 16 illustrate a method for preparing a memory structure according to a first embodiment of the present invention; and

FIG. 17(a) to FIG. 19(b) illustrate a method for preparing a memory structure according to a second embodiment of the present invention.

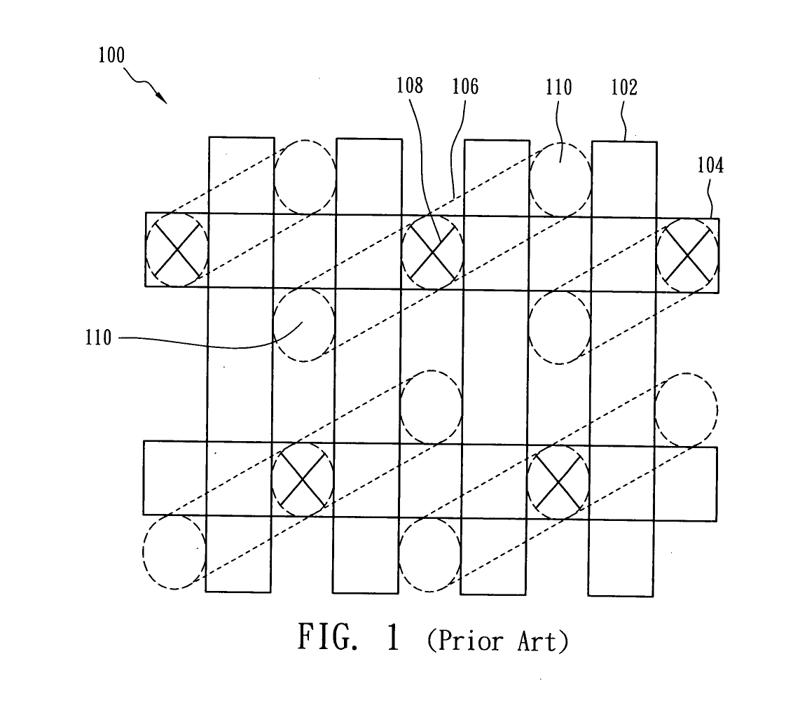

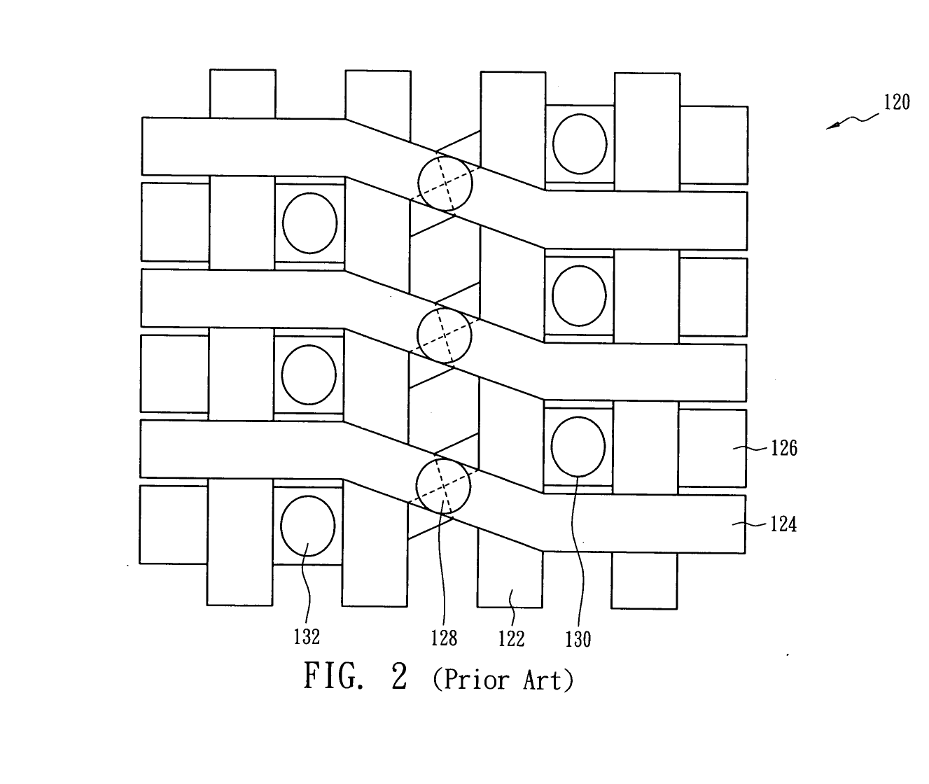

### DETAILED DESCRIPTION OF THE INVENTION

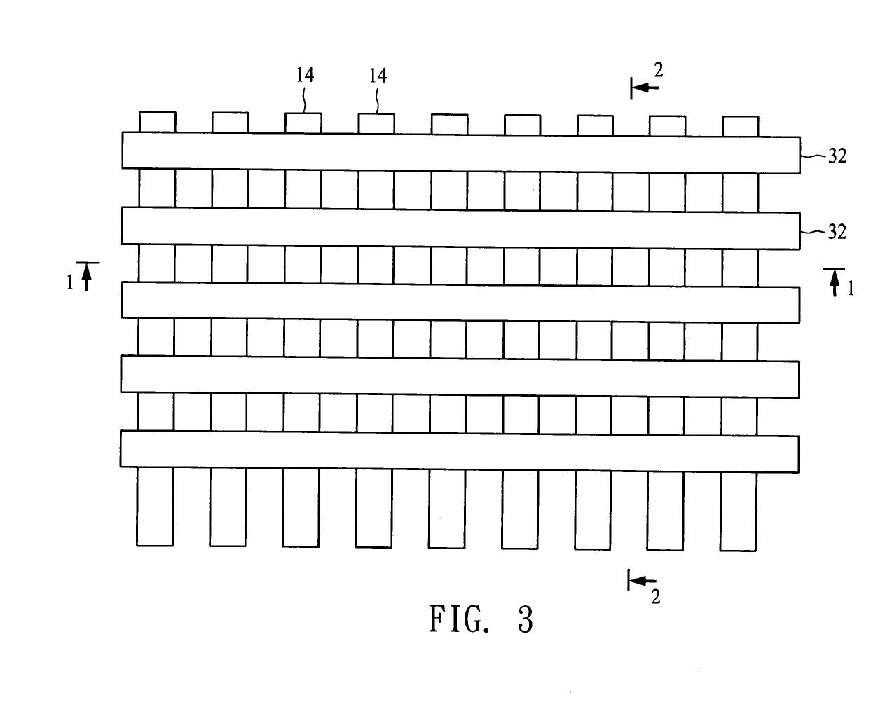

FIG. 3 to FIG. 16 illustrate a method for preparing a memory structure 10 according to a first embodiment of the present invention, wherein FIG. 3(a) and FIG. 3(b) are cross-sectional diagrams along cross-sectional lines 1-1 and 2-2 in FIG. 3, respectively. A first etching mask such as a photoresist layer 32 is formed on a substrate 30. The substrate 30 comprises a semiconductor substrate 12 such as silicon substrate, a plurality of doped regions 13A and 13B positioned in the semiconductor substrate 12, a plurality of word lines 14 positioned on the semiconductor substrate 12, a silicon nitride spacer 16 covering the sidewalls of the word lines 14, a silicon nitride layer 18 covering the surface of the semiconductor substrate 12, and a dielectric structure 20 covering the word lines 14 and the silicon nitride layer 18. The dielectric structure 20 comprises a silicon oxide layer 22 and a silicon oxide layer 24, and the first etching mask 32 is formed on the silicon oxide layer 24. The silicon oxide layer 22 may include borophosphosilicate glass (BPSG), and the silicon oxide layer 24 may include tetraethyl silicate (TEOS).

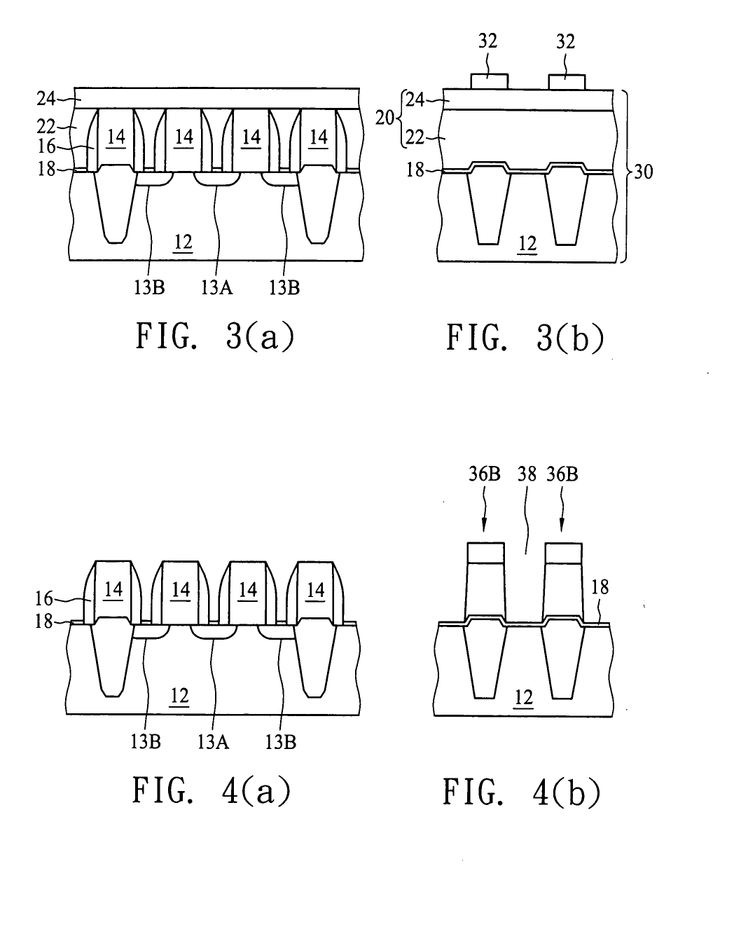

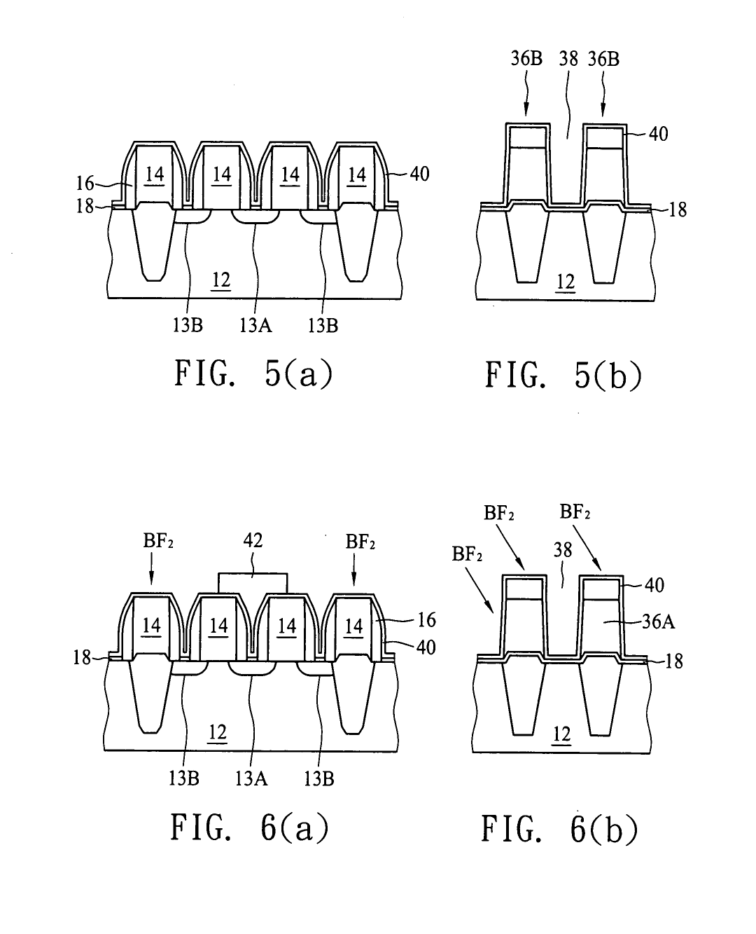

Referring to FIG. 4(a) and FIG. 4(b), these are cross-sectional diagrams along cross-sectional lines 1-1 and 2-2 in FIG. 3, respectively. An anisotropic dry etching process is performed to remove a portion of the dielectric structure 20 not covered by the first etching mask 32 down to the surface of the silicon nitride layer 18 to form a plurality of dielectric pillars 36B and a plurality of first openings 38 between the dielectric pillars 36B. Subsequently, after the first etching mask 32 is removed, a deposition process is performed to form a silicon-containing layer such as a polysilicon layer 40 covering the surface of the dielectric pillars 36B, as shown in FIG. FIG. 5(a) and FIG. 5(b), these are cross-sectional diagrams along cross-sectional lines 1-1 and 2-2 in FIG. 3, respectively

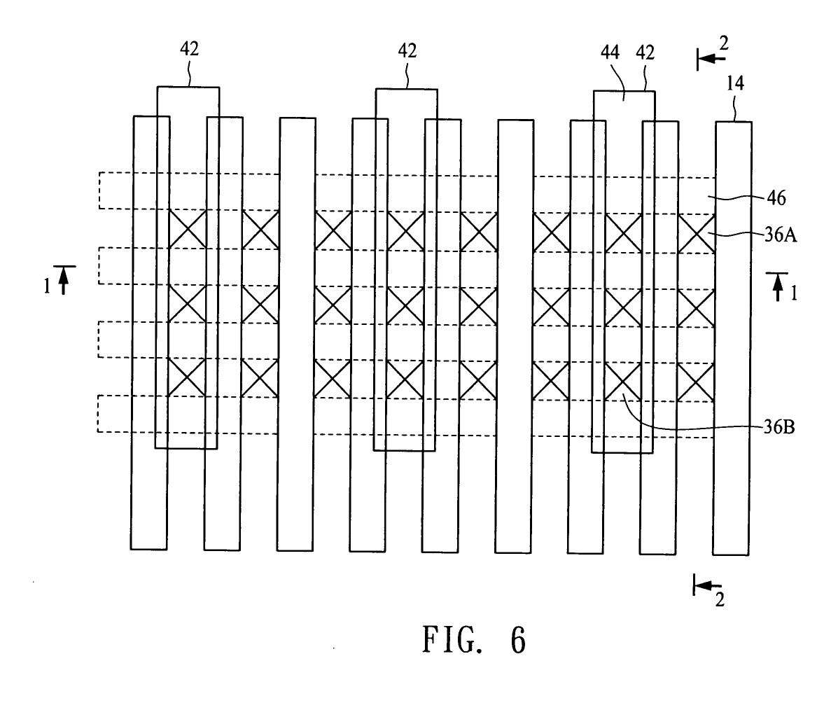

Referring to FIG. 6, FIG. 6(a) and FIG. 6(b), wherein FIG. 6(a) and FIG. 6(b) are cross-sectional diagrams along cross-sectional lines 1-1 and 2-2 in FIG. 6, respectively. A first implanting mask 42 is formed to cover some of dielectric pillars 36B in a predetermined region 44 and expose the other dielectric pillars 36A outside the predetermined region 44. The dielectric pillars 36A and 36B are positioned between the word lines 14 and the active areas 46, and the first implanting mask 42 covers the dielectric pillars 36B positioned at the middle of the active areas 46. Subsequently, a first tilt implanting process is performed to implant dopants such as boron fluoride (BF₂) into the silicon-containing layer 40 on the dielectric pillars 36A outside the predetermined region 44, as shown in FIG. 6(a) and FIG. 6(b).

In particular, the first tilt implanting process implants the dopants into a predetermined portion of the silicon-containing layer 40, i.e., the portion of the silicon-containing layer 40 on the left portion of the dielectric pillars 36A, to change its chemical property such as the etching resistance ability, while the other portion of the silicon-containing layer 40 on the right portion of the dielectric pillars 36A does not suffer dopants implanting and maintains its original chemical property.

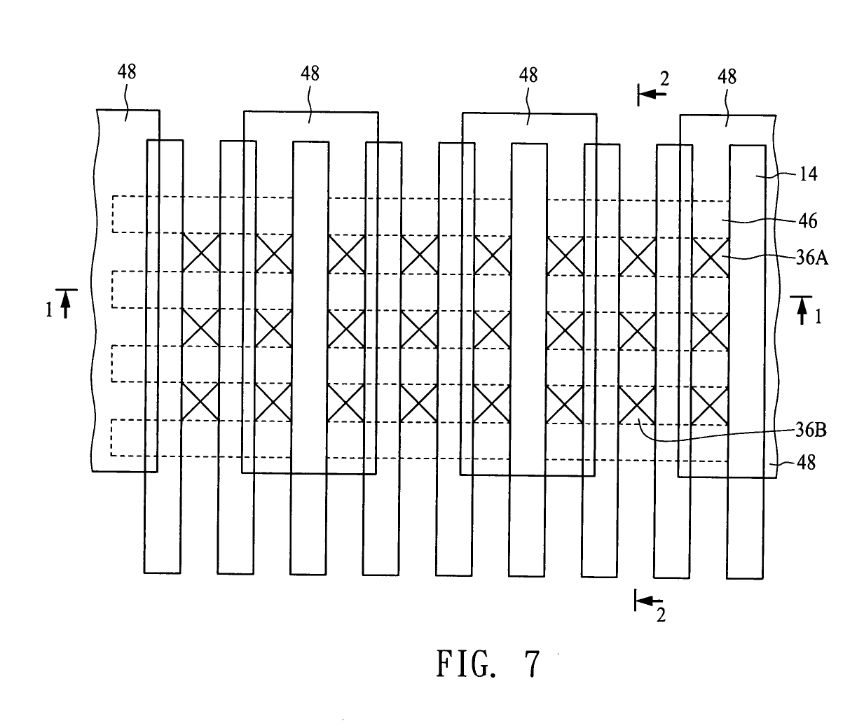

Referring to FIG. 7, FIG. 7(a) and FIG. 7(b), wherein FIG. 7(a) and FIG. 7(b) are cross-sectional diagrams along cross-sectional lines 1-1 and 2-2 in FIG. 7, respectively. After the first implanting mask 42 is removed, a second implanting mask 48 is formed to cover the dielectric pillars 36A outside the predetermined region 44 and expose the dielectric pillars 36B inside the predetermined region 44. Subsequently, a second tilt implanting process is performed to implant dopants into the silicon-containing layer 40 on the dielectric pillars 36B inside the predetermined region 44. Preferably, the implanting direction of the first tilt implanting process is opposite to the implanting direction of the second tilt implanting process. In particular, the second tilt implanting process implants the dopants into a predetermined portion of the silicon-containing layer 40, i.e., the portion of the silicon-containing layer 40 on the right portion of the dielectric pillars 36B, to change its chemical property such as the etching resistance ability, while the other portion of the silicon-containing layer 40 on the left portion of the dielectric pillars 36B does not suffer dopants implanting and maintains its original chemical property.

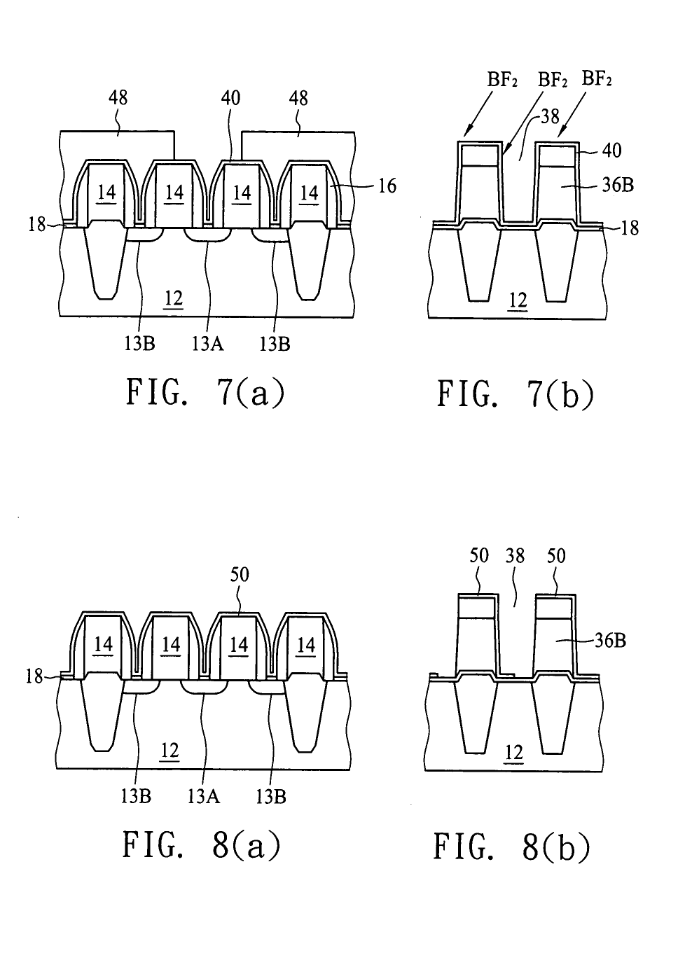

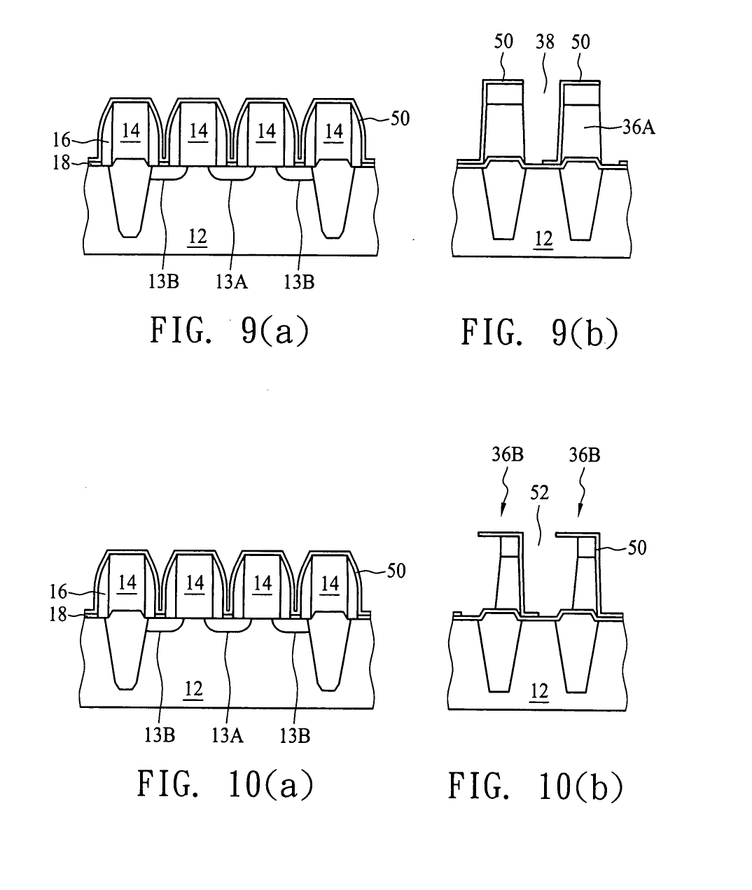

Referring to FIG. 8(a) and FIG. 8(b), these are cross-sectional diagrams along cross-sectional lines 1-1 and 2-2 in FIG. 7, respectively. After the second implanting mask 48 is removed, a wet etching process using ammonia as etchant is performed to remove a portion of the silicon-containing layer 40 other than the predetermined portion to form the second etching mask 50 such that the left sidewall of the dielectric pillars 36B is exposed. In particular, the wet etching process removes a portion of the silicon-containing layer 40 on the left portion of the dielectric pillars 36B, i.e., the portion of silicon-containing layer 40 not suffering dopants implanting is removed by the wet etching process. Similarly, the wet etching process also remove a portion of the silicon-containing layer 40 from the right portion of the dielectric pillars 36A such that the right sidewall of the dielectric pillars 36A is exposed, as shown in FIG. 9(a) and FIG. 9(b), these are cross-sectional diagrams along cross-sectional lines 1-1 and 2-2 in FIG. 6, respectively.

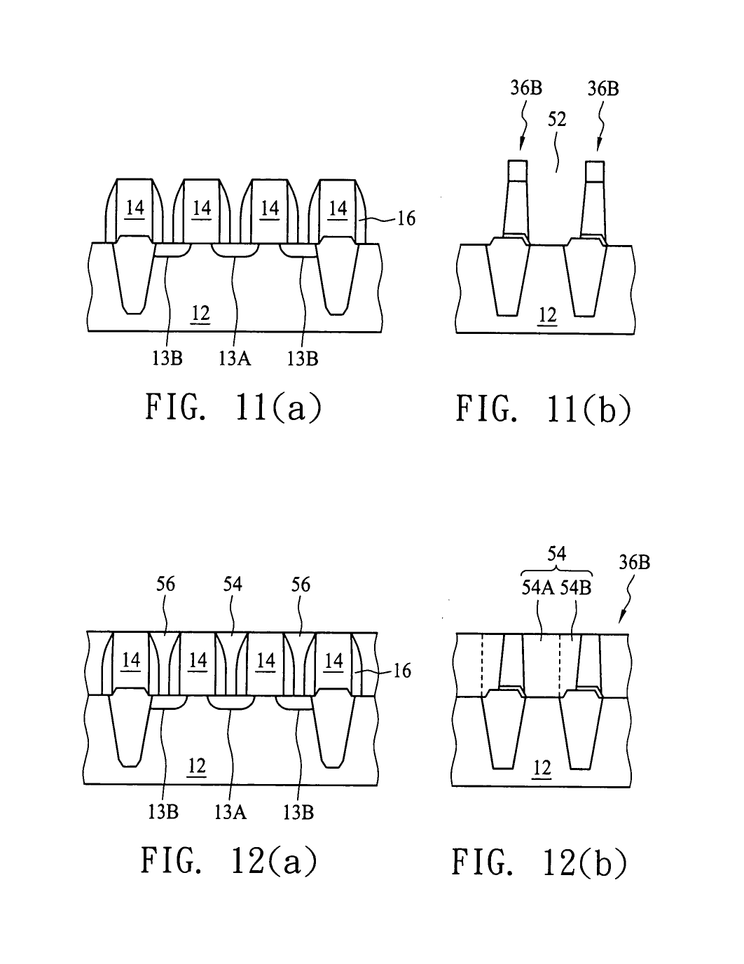

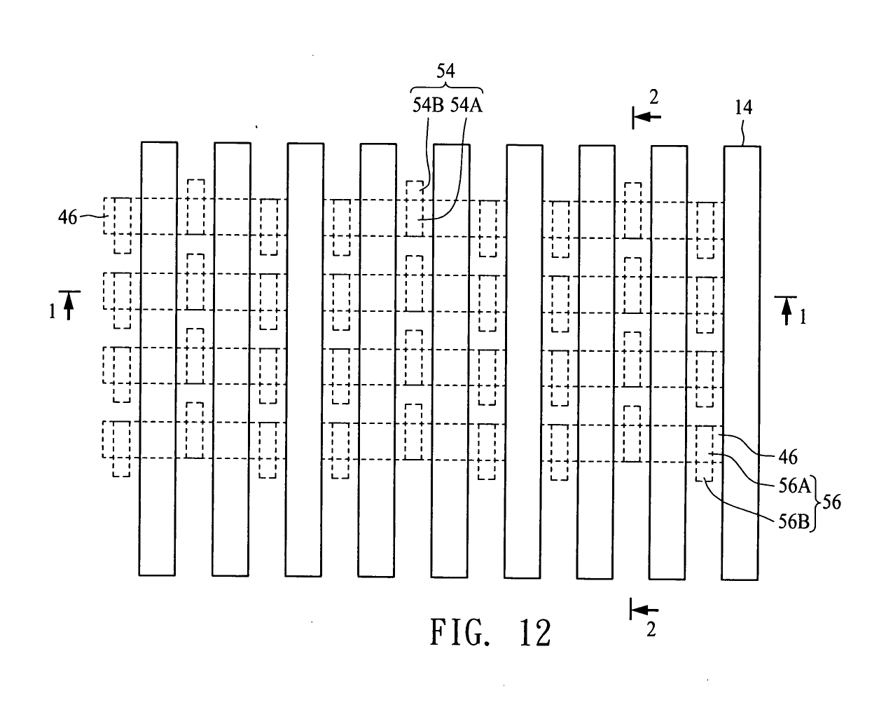

Referring to FIG. 10(a) and FIG. 10(b), these are cross-sectional diagrams along cross-sectional lines 1-1 and 2-2 in FIG. 7, respectively. Another wet etching process using the buffered oxide etchant (BOE) is performed to remove a portion of the dielectric pillars 36B not covered by the second etching mask 50. The buffered oxide etchant can etch the dielectric pillars 36B via the exposed sidewall of the dielectric pillars 36B to enlarge the first openings 38 to form second openings 52. Subsequently, an anisotropic dry etching process is performed to remove the second etching mask 50 and remove a portion of silicon nitride layer 18 to expose the doped regions 13A and 13B in the semiconductor substrate 12, as shown in FIG. 11(a) and FIG. 11(b), these are cross-sectional diagrams along cross-sectional lines 1-1 and 2-2 in FIG. 7, respectively.

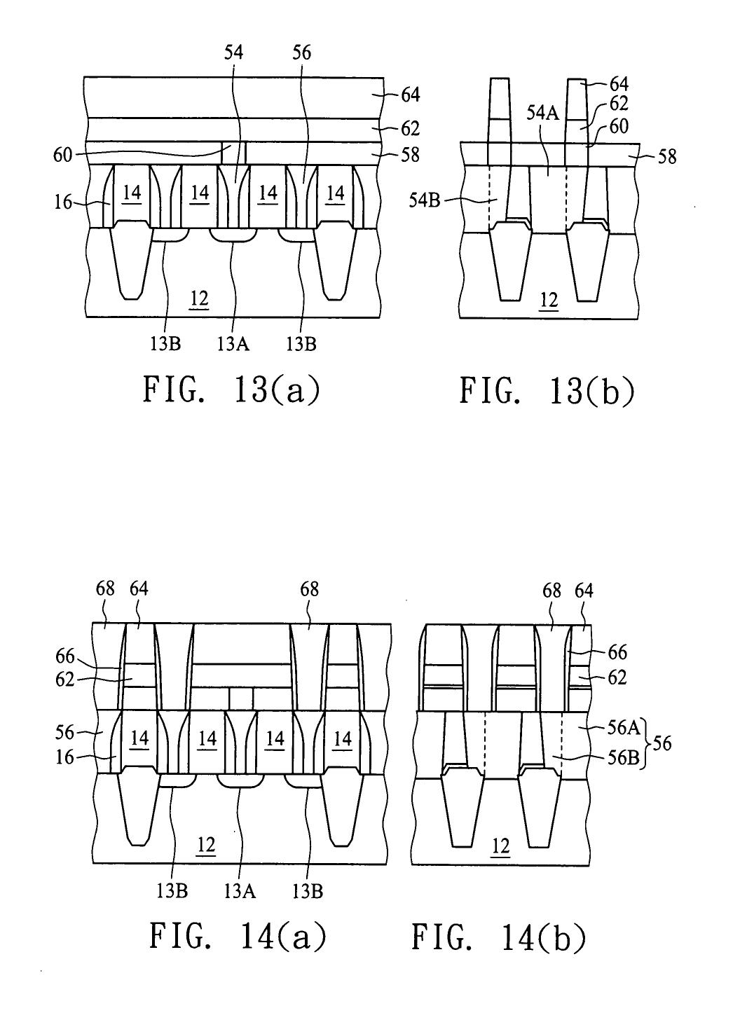

Referring to FIG. 12, FIG. 12(a) and FIG. 12(b), wherein FIG. 12(a) and FIG. 12(b) are cross-sectional diagrams along cross-sectional lines 1-1 and 2-2 in FIG. 12, respectively. A deposition process is performed to form a conductive layer such as a polysilicon layer, and a planarization process such as chemical mechanical polishing process or etch back process is then performed to remove a portion of the conductive layer to form a first conductive plug 54 in the second opening 52 inside the predetermined region 44 and a second conductive plug 56 in the second opening 52 outside the predetermined region 44.

The first conductive plug 54 includes a first block 54A positioned in the active area 46 and a second block 54B positioned at a first side of the active area 46. The second conductive plug 56 includes a third block 56A positioned in the active area 46 and a fourth block 56B positioned at a second side of the active area 46. Preferably, the width of the first block 54A is substantially twice as large as the width of second block 54B, the width of the third block 56A is substantially twice as large as the width of fourth block 56B, and the first side and the second side of the active area 46 are opposite sides of the active area 46.

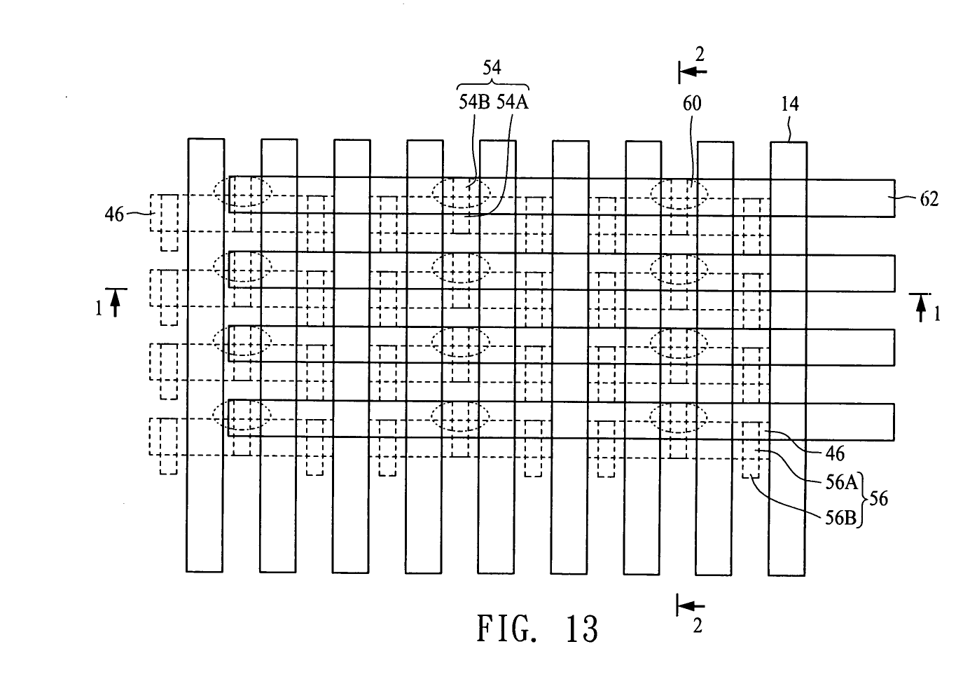

Referring to FIG. 13, FIG. 13(a) and FIG. 13(b), wherein FIG. 13(a) and FIG. 13(b) are cross-sectional diagrams along cross-sectional lines 1-1 and 2-2 in FIG. 13, respectively. A dielectric layer 58 is formed to cover the first conductive plug 54 and the second conductive plug 56, and a bit line contact plug 60 connecting the first conductive plug 54 is then formed in the dielectric layer 58. Subsequently, a conductive layer such as a tungsten layer is formed by deposition process on the dielectric layer 58 and a silicon nitride mask 64 is then formed on the conductive layer. A dry etching process is performed to remove a portion of the conductive layer not covered by the silicon nitride mask 64 to form a bit line 62 connecting the bit line contact plug 60.

To achieve the electrical connection between the bit line 62 and the doped region 13A, the bit line contact plug 60 can optionally connect either the first block 54A or the second block 54B of the first conductive plug 54. Therefore the lithographic process for patterning the size and the position of the bit line contact plug 60 possesses a wider process window. Preferably, the bit line contact plug 60 connects the second block 54B of the first conductive plug 54.

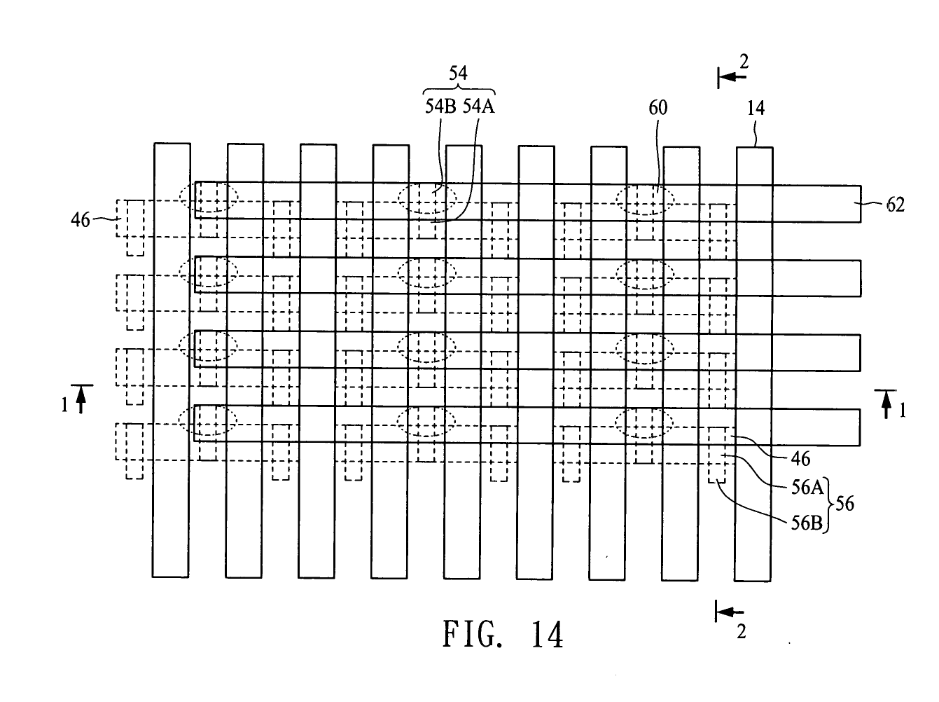

Referring to FIG. 14, FIG. 14(a) and FIG. 14(b), wherein FIG. 14(a) and FIG. 14(b) are cross-sectional diagrams along cross-sectional lines 1-1 and 2-2 in FIG. 14, respectively. A silicon nitride spacer 66 is formed to electrically isolate the bit line 62, and a high density chemical vapor phase deposition process is then performed to form a silicon oxide layer 68 filling the gap between the bit lines 62. Subsequently, a planarization process is performed to remove a portion of silicon oxide layer 68 from the silicon nitride mask 64.

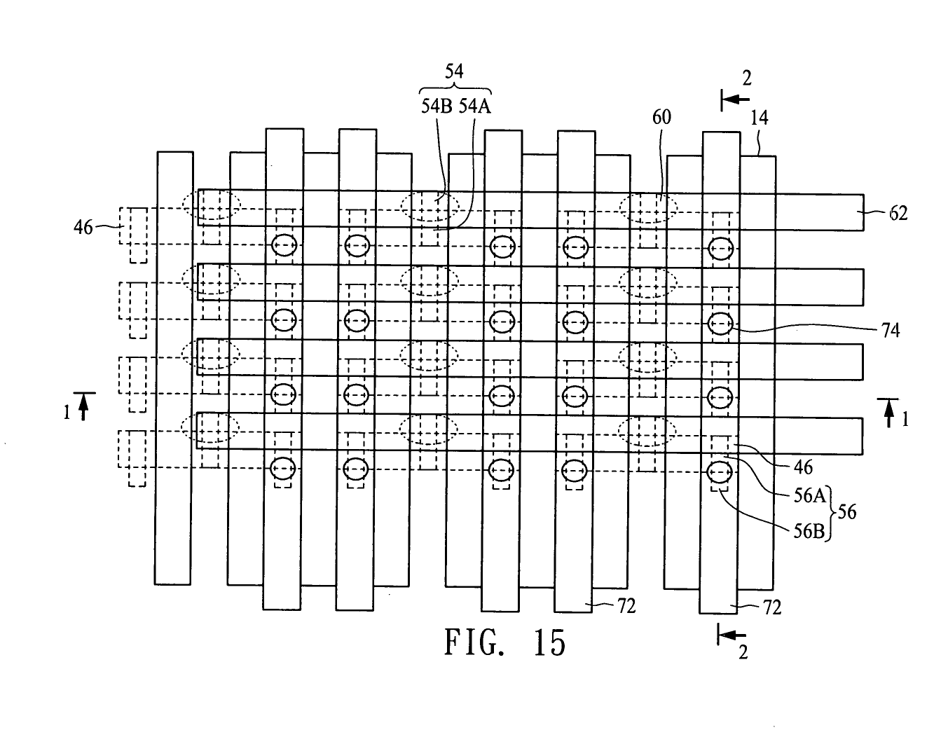

Referring to FIG. 15, FIG. 15(a) and FIG. 15(b), wherein FIG. 15(a) and FIG. 15(b) are cross-sectional diagrams along cross-sectional lines 1-1 and 2-2 in FIG. 15, respectively. A photoresist layer 70 having a plurality of line-shaped openings 72 is formed on the planarized surface, and the line-shaped opening 72 exposes a portion of the silicon oxide layer 68. Subsequently, using the photoresist layer 70 and the silicon nitride spacer 66 as the etching mask, a self-aligned dry etching process is performed to remove a portion of the silicon oxide layer 68 under the line-shaped openings 72 to form a plurality of contact holes 74 exposing the fourth block 56B of the second conductive plug 56.

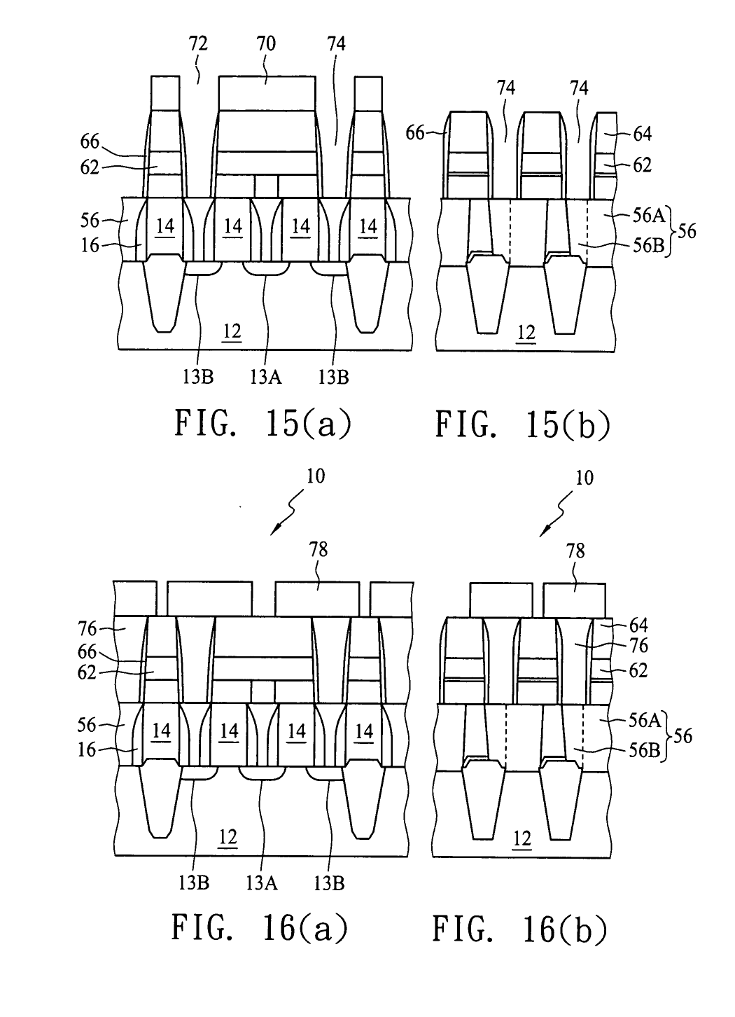

Referring to FIG. 16, FIG. 16(a) and FIG. 16(b), wherein FIG. 16(a) and FIG. 16(b) are cross-sectional diagrams along cross-sectional lines 1-1 and 2-2 in FIG. 16, respectively. A silicon nitride deposition process and a dry etching process are performed after the photoresist layer 70 is removed to increase the thickness of the silicon nitride spacer 66, and a deposition process is then performed to form a conductive layer filling the contact holes 74. Subsequently, a planarization process is performed to remove a portion of the conductive layer to form a capacitor contact plug 76 connecting the fourth block 56B of the second conductive plug 56 outside the predetermined region 44, and a plurality of capacitors 78 is then formed on the dielectric layer 64 to complete the memory structure 10. The capacitors 78 are positioned above the bit line 62, and electrically connect the fourth block 56B of the second conductive plug 56 via the capacitor contact plug 46. In particular, the two capacitors 78 connects to the capacitor contact plugs 76 in the same active area 46 are positioned at the side of the active area 46.

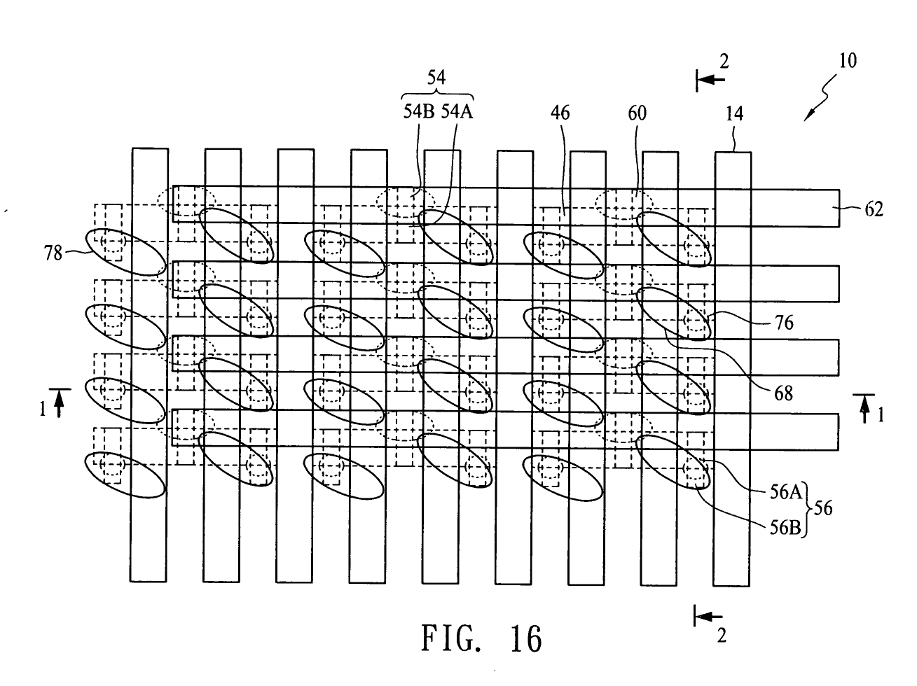

FIG. 17(a) to FIG. 19(b) illustrate a method for preparing a memory structure 10 according to a second embodiment of the present invention, these are cross-sectional diagrams along cross-sectional lines 1-1 and 2-2 in FIG. 3. First, the fabrication processes shown in FIG. 3(a), FIG. 3(b) and FIG. 4 are performed, and a liner oxide layer 82 is then formed on the silicon-containing layer 40 by deposition process. Subsequently, a spin-coating process and an etching process are performed to form a patterned photoresist layer 84 on a bottom portion of the first opening 38, as shown in FIG. 17(a) and FIG. 17(b).

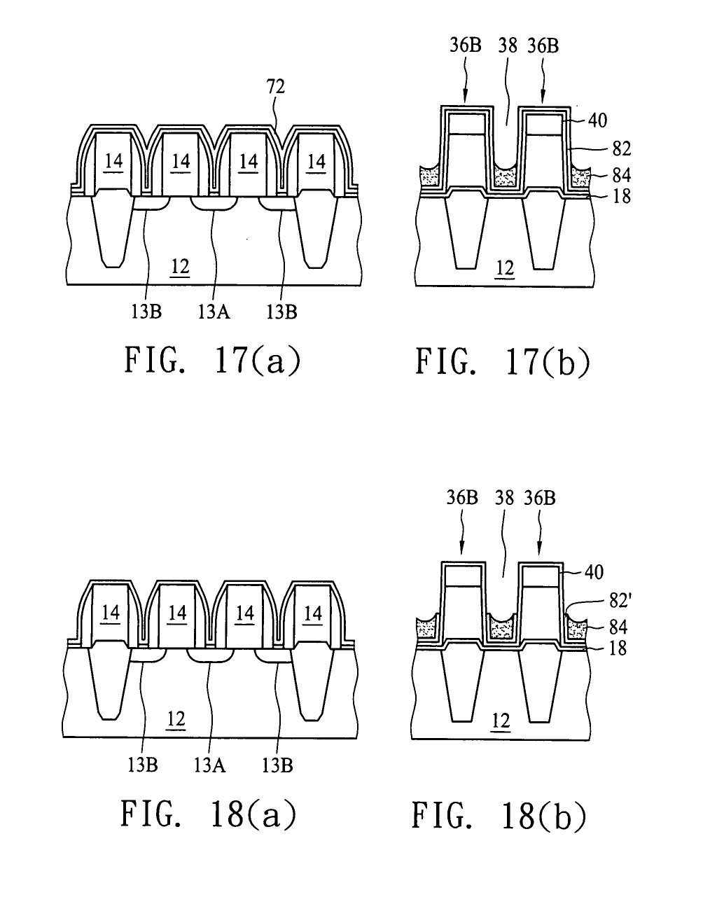

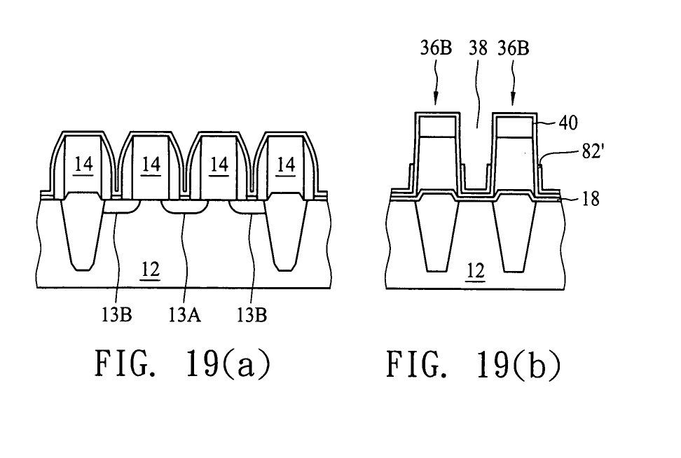

Referring to FIG. 18(a) and FIG. 18(b), an etching process is performed to remove a portion of the liner oxide layer 82 not covered by the photoresist layer 84, i.e., remove a portion of the liner oxide layer 82 from a top portion of the first opening 38. The photoresist layer 84 is then stripped to form an implanting mask 82′ on the bottom portion of the first opening 38, as shown in FIG. 19(a) and FIG. 19(b). Subsequently, the fabrication processes shown in FIG. 5(a) and FIG. 5(b) to FIG. 16 are performed to complete the memory structure 10. The implanting mask 82′ covering the bottom portion of the first openings 38 can prevent the subsequent tilt implanting processes from implanting dopants into the semiconductor substrate 12 via the first opening 38, and the implantation of dopants into the semiconductor substrate 12 may influence the electrical property of as-fabricated electronic devices.

The conventional memory structure 100 needs the double exposure technique and the advanced lithographic technique to define the size and the position of the capacitor contact plug 110, i.e., the contact hole, as the integrated circuit technique proceeds into the nanometer generation (F is smaller than 100 nanometers). In comparison, the preparation of the present memory structure 10 does not need the double exposure technique, and patterning the size and the position of the contact hole 74 (the capacitor contact plug 76) does not need the advanced lithographic technique such as liquid immersion lithographic technique.

The above-described embodiments of the present invention are intended to be illustrative only. Numerous alternative embodiments may be devised by those skilled in the art without departing from the scope of the following claims.

What is claimed is:

1. A memory structure, comprising:
a substrate;
an active area positioned in the substrate;
a first conductive plug having a first block positioned in the active area and a second block positioned at a first side of the active area; and
a second conductive plug having a third block positioned in the active area and a fourth block positioned at a second side of the active area.

2. The memory structure of claim 1, wherein the substrate comprises:
a semiconductor substrate;
a plurality of doped regions positioned in the semiconductor substrate, wherein the first conductive plug electrically connects a bit line and one of the doped regions.

3. The memory structure of claim 2, wherein the bit line connects the second block of the first conductive plug via a bit line contact plug.

4. The memory structure of claim 1, wherein the substrate comprises:
a semiconductor substrate;
a plurality of doped regions positioned in the semiconductor substrate, wherein the second conductive plug electrically connects a capacitor and one of the doped regions.

5. The memory structure of claim 4, wherein the capacitor connects the second conductive plug via a capacitor contact plug.

6. The memory structure of claim 5, wherein the capacitor contact plug connects the fourth block of the second conductive plug.

7. The memory structure of claim 1, wherein the first conductive plug electrically connects a bit line, the second conductive plug electrically connects a capacitor, and the capacitor is positioned above the bit line.

8. The memory structure of claim 1, wherein the width of the first block is substantially twice as large as the width of second block.

9. The memory structure of claim 1, wherein the width of the third block is substantially twice as large as the width of fourth block.

10. The memory structure of claim 1, wherein the first side and the second side of the active area are opposite sides of the active area.

11. The memory structure of claim 1, further comprising two capacitors positioned at the same side of the active area.

12. A method for preparing a memory structure, comprising the steps of:
forming a first etching mask on a substrate having a dielectric structure;
removing a portion of the dielectric structure to form a plurality of dielectric pillars and a plurality of first openings between the dielectric pillars;
forming a second etching mask covering a portion surface of the dielectric pillars;
removing a portion of the dielectric pillars to enlarge the first openings so as to form a plurality of second openings; and
forming a plurality of conductive plugs in the second openings.

13. The method for preparing a memory structure of claim 12, wherein the step of forming a second etching mask comprises:
forming a silicon-containing layer covering the dielectric pillars;
changing a chemical property of a predetermined portion of the silicon-containing layer; and
removing a portion of the silicon-containing layer other than the predetermined portion to form the second etching mask.

14. The method for preparing a memory structure of claim 13, wherein changing a chemical property of a predetermined portion of the silicon-containing layer is performing an implanting process to implant dopants into the predetermined portion of the silicon-containing layer.

15. The method for preparing a memory structure of claim 14, wherein the implanting process is a tilt implanting process, the silicon-containing layer includes polysilicon, and the dopants includes boron fluoride.

16. The method for preparing a memory structure of claim 14, wherein removing a portion of the silicon-containing layer other than the predetermined portion is performing a wet etching process using ammonia.

17. The method for preparing a memory structure of claim 13, wherein changing a chemical property of a predetermined portion of the silicon-containing layer comprises:
forming a first implanting mask covering the dielectric pillars in a predetermined region; and
performing a first tilt implanting process to implant dopants into the silicon-containing layer outside the predetermined region.

18. The method for preparing a memory structure of claim 17, further comprising a step of forming a plurality of bit line contact plugs connecting the conductive plugs inside the predetermined region.

19. The method for preparing a memory structure of claim 17, further comprising a step of forming a plurality of capacitor contact plugs connecting the conductive plugs outside the predetermined region.

20. The method for preparing a memory structure of claim 17, further comprising:
forming a second implanting mask exposing the dielectric pillars in the predetermined region; and
performing a second tilt implanting process to implant dopants into the silicon-containing layer inside the predetermined region;
wherein the implanting direction of the first implanting process is different from the implanting direction of the second implanting process.

21. The method for preparing a memory structure of claim 20, further comprising forming a third implanting mask covering a bottom portion of the first openings.

22. The method for preparing a memory structure of claim 20, wherein the implanting direction of the first implanting process is opposite to the implanting direction of the second implanting process.
